(19) United States
(12) Patent Application Publication
(10) Pub. No.: US 2025/0362725 A1
(43) Pub. Date: Nov. 27, 2025

(54) ON-DIE HEATING DURING MEMORY DIE OPERATION

(71) Applicant: Micron Technology, Inc., Boise, ID (US)

(72) Inventors: Ken Choong Lim, Munich (DE); Jun Tan, Weissenfeld (DE)

(21) Appl. No.: 19/190,416

(22) Filed: Apr. 25, 2025

Related U.S. Application Data
(60) Provisional application No. 63/651,372, filed on May 23, 2024.

(51) Int. Cl. G06F 1/20; G06F 11/07

(52) U.S. Cl. CPC G06F 1/206; G06F 11/073; G06F 11/0784

(57) ABSTRACT

Methods, systems, and devices for on-die heating during memory die operation are described. A memory system may be operable to monitor a temperature associated with a memory die of the memory system. Further, the memory system may be operable to activate, while the memory system is in operation and based on the temperature associated with the memory die being equal to or less than a first threshold, a heater located on the memory die and deactivate, while the memory system is in operation and based on the temperature associated with the memory die being equal to or greater than a second threshold that is greater than the first threshold, the heater located on the memory die.

### CROSS REFERENCE

The present Application for Patent claims priority to U.S. Patent Application No. 63/651,372 by Lim et al., entitled “ON-DIE HEATING DURING MEMORY DIE OPERATION,” filed May 23, 2024, which is assigned to the assignee hereof, and which is expressly incorporated by reference in its entirety herein.

### TECHNICAL FIELD

The following relates to one or more systems for memory, including on-die heating during memory die operation.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports on-die heating during memory die operation in accordance with examples as disclosed herein.

FIG. 2A shows an example of a memory system that supports on-die heating during memory die operation in accordance with examples as disclosed herein.

FIG. 2B shows an example of a graph that supports on-die heating during memory die operation in accordance with examples as disclosed herein.

FIG. 3 shows a block diagram of a memory system that supports on-die heating during memory die operation in accordance with examples as disclosed herein.

FIG. 4 shows a flowchart illustrating a method or methods that support on-die heating during memory die operation in accordance with examples as disclosed herein.

### DETAILED DESCRIPTION

A memory system may operate in different temperature environments. For example, the memory system may operate in a cold temperature environment (e.g., sub-zero temperature environment) or a room temperature environment (e.g., ambient temperature environment). In some examples, as the memory system moves from one temperature environment to another, a temperature of the memory system may change (e.g., equalize with the temperature environment). One or more properties of the memory system (e.g., carrier mobility, threshold voltage, or polysilicon resistance) may be temperature dependent, resulting in different characteristics of the memory system at different temperature environments. As a result, when the memory system operates in the cold temperature environment, some features of the memory system may not satisfy one or more operational thresholds (e.g., the memory system may not comply with datasheet operational specifications). Thus, it may be beneficial to maintain the temperature of the memory system (or critical silicon areas of the memory system) within a temperature range (e.g., −30 degrees Celsius to 125 degrees Celsius for automotive applications, or some other temperature range) while the memory system operates in an ambient temperature environment such that features of the memory system satisfy the one or more operational thresholds.

As described herein, a memory system may include an on-die heater that is configured to heat the memory system while a state of the heater is set to an activated state and while the memory system is in operation. In some examples, one or more controllers may receive, from a temperature sensor, a first temperature associated with a memory die of the memory system and compare the first temperature to a first threshold (e.g., −35 degrees Celsius or some other threshold temperature) and a second threshold (e.g., −30 degrees Celsius or some other threshold temperature) greater than the first threshold. If the first temperature is equal to or less than the first threshold, the one or more controllers may transmit an activation signal to set the state of the heater to the activated state.

At a different time (e.g., while the heater is activated), the one or more controllers may receive, from the temperature sensor, a second temperature associated with the memory die and compare the second temperature to the first threshold and the second threshold. If the second temperature is equal to or greater than the second threshold, the one or more controllers may transmit a deactivation signal to set the state of the heater to a deactivated state. Using the on-die heater as described herein may allow the memory system to improve memory storage characteristics by maintaining the temperature of the memory system within the temperature range regardless of the temperature environment in which the memory system operates.

In addition to applicability in memory systems as described herein, techniques for on-die heating during memory die operation may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by increasing component endurance over time, which may extend the life of electronic devices and reduce electronic waste, among other benefits.

Features of the disclosure are illustrated and described in the context of systems and architectures. Features of the disclosure are further illustrated and described in the context of a memory system, a graph, and flowcharts.

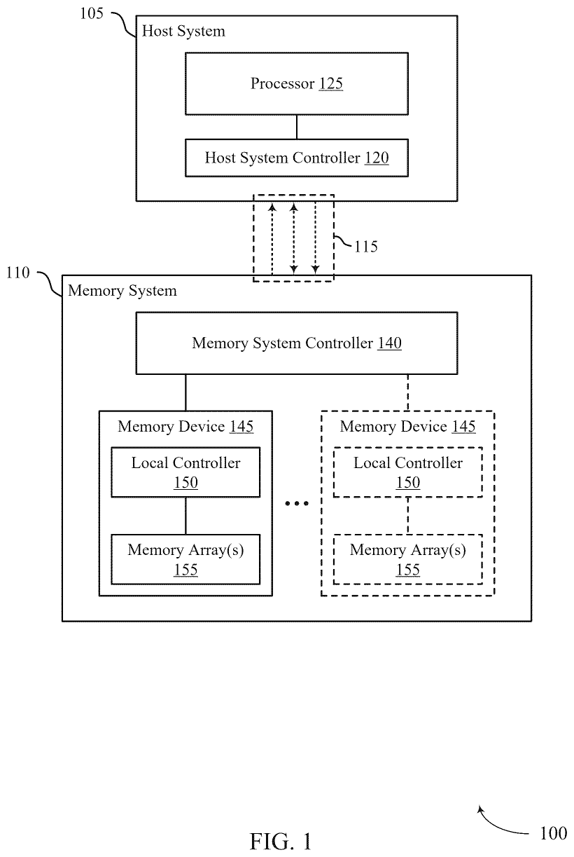

FIG. 1 illustrates an example of a system 100 that supports on-die heating during memory die operation in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

As described herein, a memory system 110 may include an on-die heater that is configured to heat the memory system 110 while a state of the heater is set to an activated state and while the memory system 110 is in operation. In some examples, one or more controllers (e.g., the memory system controllers 140 or the local controllers 150) may receive, from a temperature sensor, a first temperature associated with the memory die 145 and compare the first temperature to a first threshold and a second threshold greater than the first threshold. The one or more controllers may identify that the first temperature is equal to or less than the first threshold and transmit an activation signal to set the state of the heater to the activated state.

At a later time, the one or more controllers may receive, from the temperature sensor, a second temperature associated with the memory die and compare the second temperature to the first threshold and the second threshold. The one or more controllers may identify that the second temperature is equal to or greater than the second threshold and transmit a deactivation signal to set the state of the heater to a deactivated state. Using the on-die heater as described herein may allow the memory system 110 to optimize characteristics of the memory system by maintaining the temperature of the memory system 110 within the temperature range regardless of the temperate environment in which the memory system 110 operates.

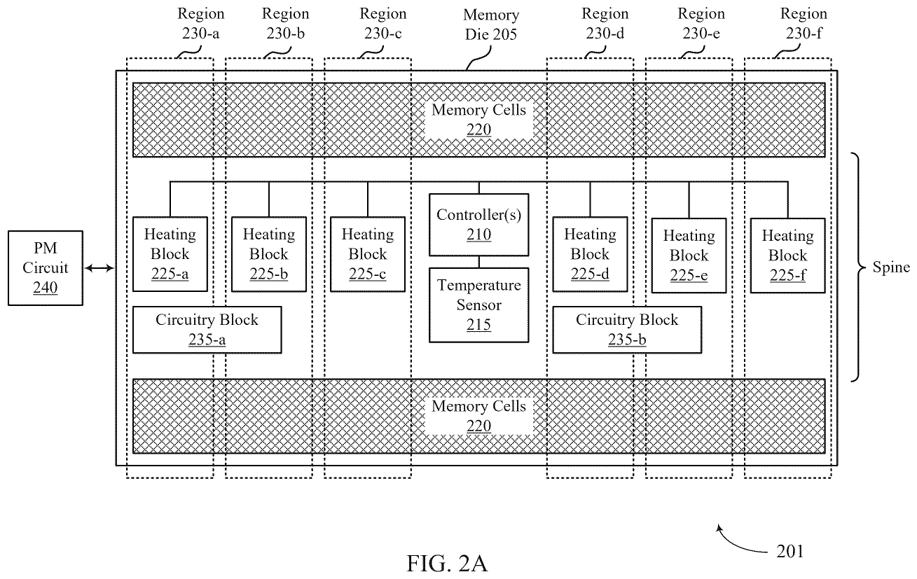

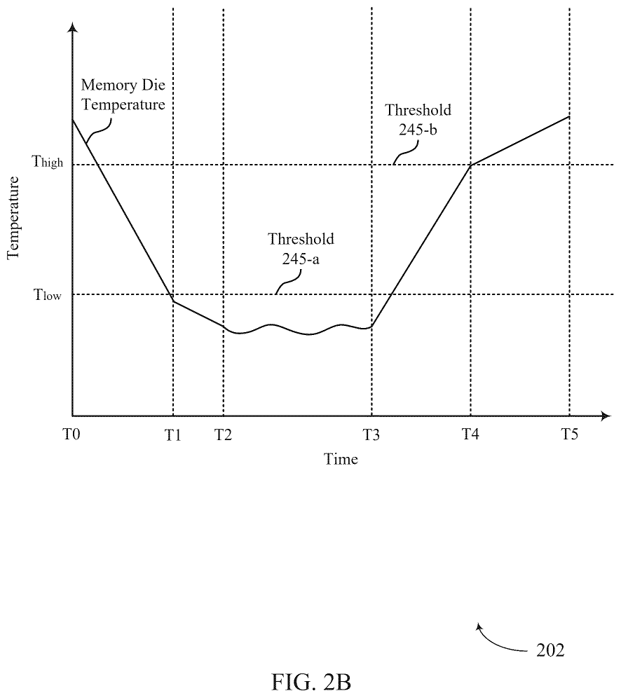

FIG. 2A shows an example of a memory system 201 that supports on-die heating during memory die operation in accordance with examples as disclosed herein. In some examples, the memory system 201 may implement aspects of a system 100. For example, the memory system 201 may include a memory die 205 which may be an example of a memory die 145 as described with reference to FIG. 1. Further, the memory die 205 may include a controller 210 which may be an example of a memory system controller 140 or a local controller 150 as described with reference to FIG. 1.

FIG. 2B shows an example of a graph 202 that supports on-die heating during memory die operation in accordance with examples as disclosed herein. In some examples, aspects of the graph 202 may be implemented by aspects of the system 100. For example, aspects of the graph 202 may be implemented by a memory device 145 as described with reference to FIG. 1.

In some examples, the memory die 205 may include memory cells 220 divided into one or more memory portions. As shown in FIG. 2A, the memory cells 220 of the memory die 205 may be divided into two memory portions (e.g., a top memory portion and a bottom memory portion, or some other portions). The memory portions may be separated by a space known as a “spine” of the memory die 205. The spine may be an area that is central or near a center of the memory die 205 at least along one axis and may include circuitry to support functionality of the memory die 205. For example, as shown in FIG. 2A, the memory system 201 may include one or more circuitry blocks 235 (e.g., a circuitry block 235-a and a circuitry block 235-b) which may be located on the spine of the memory die 205 or at locations adjacent to the spine of the memory die 205. In some examples, each memory portion may include multiple banks of memory cells 220. For example, each of the two memory portions may include four bank groups and each bank group may include four banks of memory cells 220.

During operation, the memory die 205 may undergo fluctuations in temperature. For example, the memory die 205 may operate at a low temperature of −20 degrees Celsius during a first period of operation and operate at a high temperature of 80 degrees Celsius during a second period of operation, or some other operating temperatures. In some examples, some features of the memory die 205 may satisfy one or more operational thresholds if a temperature of the memory die 205 is maintained within some range of temperature. As an example, the range of temperature may include a range of −30 degrees Celsius to 125 degrees Celsius. If the memory die 205 operates at a temperature outside the range of temperatures (e.g., −45 degrees Celsius), some of the features of the memory die 205 may not satisfy the one or more operational thresholds resulting in a decrease in performance of the memory die 205.

To reduce a likelihood that the memory die 205 operates at a temperature outside the range of temperatures or operates at a temperature outside the range of temperature for a threshold period of operation, the memory die 205 may include a heater operable to dissipate heat to the memory die 205. The heater may include a set of heating blocks 225 (e.g., a heating block 225-a, a heating block 225-b, a heating block 225-c, a heating block 225-d, a heating block 225-e, a heating block 225-f). Further, the set of heating blocks 225 may be coupled with one or more controllers 210 of the memory die 205 and the one or more controllers 210 may be coupled with a temperature sensor 215 of the memory die 205.

In some examples, each heating block 225 of the set of heating blocks 225 may include one or more heating elements configured to generate at least a portion of the heat dissipated to the memory die 205 and each heating element may include one or more transistors. For example, each heating element may include at least a first transistor. A first node of the first transistor (or source) may be coupled with a voltage source, the second node of the first transistor (or drain) may be coupled with ground, and the third node of the first transistor (or gate) may be coupled with the one or more controllers 210.

In response to an activation signal from the one or more controllers 210, the first transistor may switch to an “ON” state and current may flow from the voltage source to ground. Alternatively, in response to a deactivation signal from the one or more controllers 210, the first transistor may switch to an “OFF” state and current may stop flowing from the voltage source to ground. In some examples, each heating block 225 may be associated with a respective heating level. A heating level may refer to a quantity of heating elements that are enabled at the respective heating block 225. In some examples, the heating level for a heating block 225 may be pre-configured at the memory system 201 (e.g., prior to operation). Alternatively, the heating level for a heating block 225 may dynamically change during operation via a signal from the one or more controllers 210 (e.g., the activation signal).

As shown in FIG. 2A, the set of heating blocks 225 of the heater may be located on the spine of the memory die 205 (or may be integrated with the circuitry of the spine). For example, the set of heating blocks 225 may be distributed across the spine such that a distance (e.g., a horizontal distance) between each consecutive heating block 225 of the set is equal. Further, in some examples, the set of heating blocks 225 may be located along a center line of the spine or situated equidistance between the memory portions. As another option, a first subset of the set of heating blocks 225 may be located along the center line of the spine while a second subset of the set of heating blocks 225 may be vertically offset from the center line of the spine.

In some examples, the heating blocks 225 may be divided into two groups: a first group of heating blocks 225 (e.g., the heating block 225-a, the heating block 225-b, and the heating blocks 225-c) and a second group (e.g., the heating block 225-d, the heating block 225-e, and the heating blocks 225-f). As shown in FIG. 2A, the first group of heating blocks 225 may occupy a left half of the memory die 205 (e.g., a first channel of the memory die) and the second group of heating blocks 225 may occupy a right half of memory die 205 (e.g., a second channel of the memory die).

The one or more controllers 210 and the temperature sensor 215 may also be located on the spine. In some examples, the one or more controllers 210 and the temperature sensor 215 may be centrally located on the spine. For example, the one or more controllers 210 and the temperature sensor 215 may be situated between the two groups of heating blocks 225. Although FIG. 2A illustrates the one or more controllers 210, the temperature sensor 215, and the set of heating blocks 225 at particular locations on the spine of the memory die 205, it is understood that these components may be at locations on the memory die 205 different from those illustrated in FIG. 2A.

During operation, the heater may be configured to heat the memory die 205 using the set of heating blocks 225 based on a temperature of the memory die 205 monitored by the temperature sensor 215. In some examples, each heating block 225 may correspond to a different region 230 of the memory die 205. For example, the heating block 225-a, the heating block 225-b, the heating block 225-c, the heating block 225-d, the heating block 225-e, and the heating block 225-f may corresponds to a region 230-a, a region 230-b, a region 230-c, a region 230-d, a region 230-e, and a region 230-f, respectively. Each region 230 may cover at least a percentage of a memory portion (e.g., one or more banks) of the memory die 205. When in an activated state, a heating block 225 may be configured to dissipate heat to its respective region 230. Alternatively, when in a deactivated state, the heating block 225 may be configured to not dissipate heat to its respective region 230.

FIG. 2B illustrates a temperature of the memory die 205 during a period of operation (e.g., T0 to T5). From T0 to T5, the temperature sensor 215 may monitor the temperature of the memory die 205 and report the temperature of the memory die 205 to the one or more controllers 210 at different time points (e.g., T0, T1, T2, T3, T4, and T5). In some examples, the temperature sensor 215 may report the temperature of the memory die 205 in a periodic or aperiodic manner.

In some examples, the heater may implement an on-off control system. For example, one or more heating blocks 225 may transition to the activated state when a temperature of the memory die 205 meets or is below a threshold 245-a (or T_{low}). Alternatively, the one or more heating blocks 225 may transition to the deactivated state when a temperature of the memory die 205 meets or is above a threshold 245-b (or T_{high}). In some examples, the threshold 245-a may be less than the threshold 245-b. For example, the threshold 245-b may be equal to −30 degrees Celsius, or some other temperature threshold, while the threshold 245-a may be equal to −35 degrees Celsius, or some other temperature threshold. The thresholds may be configured during manufacture of the memory system (e.g., based on sensitivity of the system to high or low temperatures), may be set by a user of the system, may be based on one or more other parameters, or any combination thereof.

The following describes one or more actions performed by the heater, the one or more controllers 210, and the temperature sensor 215 while operating in accordance to the on-off control system.

At T0, the temperature sensor 215 may transmit a signal to the one or more controllers 210 indicating the temperature at TO (or a first temperature). In response to the signal, the one or more controllers 210 may compare the first temperature to the thresholds 245 (e.g., the threshold 245-b and the threshold 245-a). The one or more controllers 210 may determine that the first temperature is above the threshold 245-b and generate a deactivation signal to set the state of the one or more heating blocks 225 to a deactivated state. The one or more controllers 210 may transmit the deactivation signal to the one or more heating blocks 225 and in response to the deactivation signal, the set of heating blocks 225 may switch from an activated state to the deactivated state or remain in the deactivated state. In some examples, after (e.g., in response to, based on) determining the first temperature is above the threshold 245-b, the one or more controllers 210 may receive a negative error signal and generate the deactivation signal in response to receiving the negative error signal. From T0 to T1, the memory die 205 may be introduced to a low temperature environment (e.g., a sub-zero temperature environment) causing the temperature of the memory die 205 to decrease at a first rate.

At T1, the temperature sensor 215 may transmit a signal to the one or more controllers 210 indicating the temperature at T1 (or a second temperature). In response to the signal, the one or more controllers 210 may compare the second temperature to the thresholds 245 (e.g., the threshold 245-b and the threshold 245-a). The one or more controllers 210 may determine that the second temperature is below the threshold 245-a and generate an activation signal to set the state of the one or more heating blocks 225 to the activated state. The one or more controllers 210 may transmit the activation signal to the one or more heating blocks 225 and in response to the deactivation signal, the set of heating blocks 225 may switch from the deactivated state to the activated state. In the activated state, the set of heating blocks 225 may dissipate heat which may slow down memory die cooling. For example, from T1 to T2, the temperature of the memory die 205 may decrease at a second rate which may be less than the first rate.

In some examples, after determining the first temperature is below the threshold 245-a, the one or more controllers 210 may receive a positive error signal and generate the activation signal in response to receiving the positive error signal. In other words, the transition between the activated stated and the deactivated state is governed by the sign of the error signal. When the error signal is positive, the one or more controllers 210 generate the activated signal and when the error signal is negative, the one or more controllers 210 generate the deactivation signal.

From T2 to T3, the state of the one or more heating blocks 225 may remain in the activated state and the temperature of the memory die 205 may fluctuate as the memory die 205 operates in the low temperature environment. While in the activated state, the one or more heating blocks 225 may dissipate heat such that the temperature of the memory die 205 is maintained at a temperature that is within the range of temperatures (e.g., above-30 degrees).

From T3 to T4, the temperature of the memory die 205 may increase as the memory die 205 moves from the low temperature environment to a high temperature environment (e.g., an ambient temperature environment). Although the memory die 205 moves to the high temperature environment, the temperature of the memory die 205 may remain below the threshold 245-b. Thus, the state of the one or more heating blocks 225 may remain in the activated state from T3 to T4.

At T4, the temperature sensor 215 may transmit a signal to the one or more controllers 210 indicating the temperature at T4 (or a third temperature). In response to the signal, the one or more controllers 210 may compare the third temperature to the thresholds 245 (e.g., the threshold 245-b and the threshold 245-a). The one or more controllers 210 may determine that the third temperature is above the threshold 245-b and generate the deactivation signal to set the state of the one or more heating blocks 225 to the deactivated state. The one or more controllers 210 may transmit the deactivation signal to the one or more heating blocks 225 and in response to the deactivation signal, the set of heating blocks 225 may switch from the activated state to the deactivated state. In some examples, after determining the third temperature is above the threshold 245-b, the one or more controllers 210 may receive the negative error signal and generate the deactivation signal in response to receiving the negative error signal. From T4 to T5, the temperature of the memory die 205 may continue to increase while the temperature of the memory die 205 slowly equalize with the high temperature environment.

In some examples, a distance between respective heating blocks 225 and respective circuitry blocks 235 may vary. For example, as shown in FIG. 2A, the heating block 225-a may be in closer proximity to (e.g., a shorter distance away from) the circuitry block 235-a than the heating block 225-c. Temperature changes may affect the circuitry blocks 235 more so than other components of the memory system 201. Thus, heating blocks 225 closer to the circuitry blocks 235 may be associated with different thresholds 245. For example, the threshold 245-a for the heating block 225-a may be different than the threshold 245-a for the heating block 225-c. As an example, the threshold 245-a for the heating block 225-a may be equal to −32 degrees Celsius and the threshold 245-a for the heating block 225-c may be equal to −35 degrees Celsius. In such examples, if the one or more controllers 210 detect that the temperature of the memory die 205 is less than the threshold 245-a for the heating block 225-a and greater than the threshold 245-a for the heating block 225-c, the one or more controllers 210 may set the state of the state of the heating block 225-a to the activated state (e.g., via the activation signal) and set the state of the heating block 225-c to the deactivated state (e.g., via the deactivation signal).

Further, in some examples, the one or more controllers 210 may identify whether one or more conditions associated with the memory system 201 are satisfied and generate either the activation signal or the deactivation signal in response to identifying whether the one or more conditions are satisfied. The one or more controllers 210 may identify that the one or more conditions are satisfied if the one or more controllers 210 identify that a quantity of commands (e.g., access commands) satisfies (or exceeds) a first threshold, or an input power of the memory system 201 satisfies (or exceeds) a second threshold.

As shown in FIG. 2A, the memory system 201 may include a power management circuit 240 coupled with the memory die 205, or more specifically, the one or more controllers 210. The power management circuit 240 may be configured to monitor an input voltage of the memory system 201 and transmit signaling to the one or more controllers 210 indicating the input voltage of the memory system 201. If the input power exceeds the second threshold, the one or more controllers 210 may identify that the one or more conditions are satisfied and refrain from generating the activation signal (even if the temperature of the memory die 205 meets or is below the threshold 245-a). Alternatively, if the input power is below the second threshold, the one or more controllers 210 may identify that the one or more conditions are not satisfied and generate the activation signal when the temperature of the memory die 205 meets or is below the threshold 245-a. Using the methods as described herein may allow the memory die 205 to operate within the temperature range resulting in increased reliability of the memory die 205.

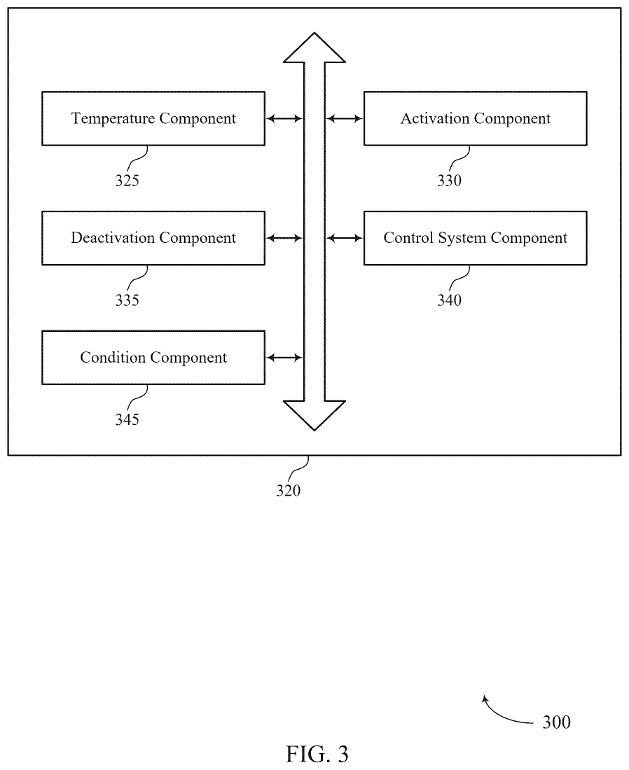

FIG. 3 shows a block diagram 300 of a memory system 320 that supports on-die heating during memory die operation in accordance with examples as disclosed herein. The memory system 320 may be an example of aspects of a memory system as described with reference to FIGS. 1, 2A, and 2B. The memory system 320, or various components thereof, may be an example of means for performing various aspects of on-die heating during memory die operation as described herein. For example, the memory system 320 may include a temperature component 325, an activation component 330, a deactivation component 335, a control system component 340, a condition component 345, or any combination thereof. Each of these components, or components of subcomponents thereof (e.g., one or more processors, one or more memories), may communicate, directly or indirectly, with one another (e.g., via one or more buses).

The temperature component 325 may be configured as or otherwise support a means for monitoring a temperature associated with a memory die of the memory system. The activation component 330 may be configured as or otherwise support a means for activating, while the memory system is in operation and based at least in part on the temperature associated with the memory die being equal to or less than a first threshold, a heater located on the memory die, the activating increasing the temperature associated with the memory die. The deactivation component 335 may be configured as or otherwise support a means for deactivating, while the memory system is in operation and based at least in part on the temperature associated with the memory die being equal to or greater than a second threshold that is greater than the first threshold, the heater located on the memory die.

In some examples, to support deactivating the heater, the deactivation component 335 may be configured as or otherwise support a means for decreasing the temperature associated with the memory die. In some examples, to support deactivating the heater, the deactivation component 335 may be configured as or otherwise support a means for maintaining the temperature associated with the memory die.

In some examples, the control system component 340 may be configured as or otherwise support a means for receiving a positive error signal based at least in part on the temperature associated with the memory die being equal to or less than the first threshold, where activating the heater is based at least in part on the positive error signal. In some examples, the control system component 340 may be configured as or otherwise support a means for receiving a negative error signal based at least in part on the temperature associated with the memory die being greater than or equal to the second threshold, where deactivating the heater is based at least in part on the negative error signal.

In some examples, the condition component 345 may be configured as or otherwise support a means for identifying whether one or more conditions associated with the memory system are met, where the one or more conditions include a quantity of commands associated with the memory system satisfying a third threshold, an input voltage associated with the memory system satisfying a fourth threshold, or a combination thereof.

In some examples, the condition component 345 may be configured as or otherwise support a means for monitoring the input voltage associated with the memory system, where identifying whether the one or more conditions associated with the memory system are met based at least in part on monitoring the input voltage associated with the memory system.

In some examples, the activation component 330 may be configured as or otherwise support a means for activating the heater based at least in part on identifying that the one or more conditions are not met. In some examples, the deactivation component 335 may be configured as or otherwise support a means for deactivating the heater based at least in part on identifying that the one or more conditions are met.

In some examples, the first threshold includes a temperature of negative 35 degrees Celsius and the second threshold includes a temperature of negative 30 degrees Celsius.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

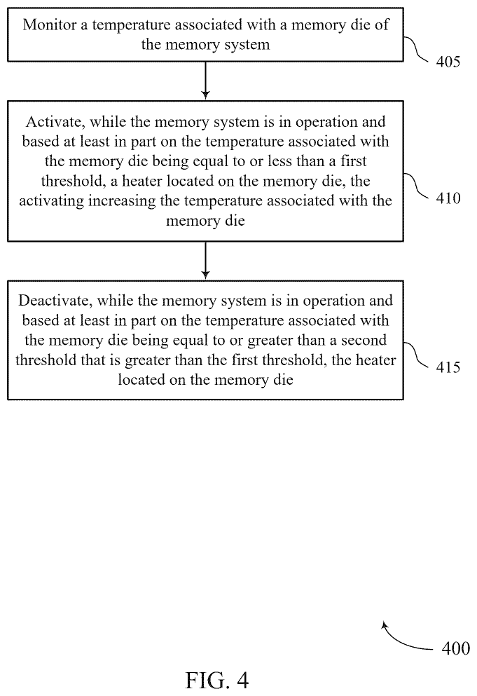

FIG. 4 shows a flowchart illustrating a method 400 that supports on-die heating during memory die operation in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include monitoring a temperature associated with a memory die of the memory system. In some examples, aspects of the operations of 405 may be performed by a temperature component 325 as described with reference to FIG. 3.

At 410, the method may include activating, while the memory system is in operation and based at least in part on the temperature associated with the memory die being equal to or less than a first threshold, a heater located on the memory die, the activating increasing the temperature associated with the memory die. In some examples, aspects of the operations of 410 may be performed by an activation component 330 as described with reference to FIG. 3.

At 415, the method may include deactivating, while the memory system is in operation and based at least in part on the temperature associated with the memory die being equal to or greater than a second threshold that is greater than the first threshold, the heater located on the memory die. In some examples, aspects of the operations of 415 may be performed by a deactivation component 335 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for monitoring a temperature associated with a memory die of the memory system; activating, while the memory system is in operation and based at least in part on the temperature associated with the memory die being equal to or less than a first threshold, a heater located on the memory die, the activating increasing the temperature associated with the memory die; and deactivating, while the memory system is in operation and based at least in part on the temperature associated with the memory die being equal to or greater than a second threshold that is greater than the first threshold, the heater located on the memory die.

Aspect 2: The method, apparatus, or non-transitory computer-readable medium of aspect 1, where deactivating the heater includes operations, features, circuitry, logic, means, or instructions, or any combination thereof for decreasing the temperature associated with the memory die and maintaining the temperature associated with the memory die.

Aspect 3: The method, apparatus, or non-transitory computer-readable medium of any of aspects 1 through 2, further including operations, features, circuitry, logic, means, or instructions, or any combination thereof for receiving a positive error signal based at least in part on the temperature associated with the memory die being equal to or less than the first threshold, where activating the heater is based at least in part on the positive error signal and receiving a negative error signal based at least in part on the temperature associated with the memory die being greater than or equal to the second threshold, where deactivating the heater is based at least in part on the negative error signal.

Aspect 4: The method, apparatus, or non-transitory computer-readable medium of any of aspects 1 through 3, further including operations, features, circuitry, logic, means, or instructions, or any combination thereof for identifying whether one or more conditions associated with the memory system are met, where the one or more conditions include a quantity of commands associated with the memory system satisfying a third threshold, an input voltage associated with the memory system satisfying a fourth threshold, or a combination thereof.

Aspect 5: The method, apparatus, or non-transitory computer-readable medium of aspect 4, further including operations, features, circuitry, logic, means, or instructions, or any combination thereof for monitoring the input voltage associated with the memory system, where identifying whether the one or more conditions associated with the memory system are met based at least in part on monitoring the input voltage associated with the memory system.

Aspect 6: The method, apparatus, or non-transitory computer-readable medium of any of aspects 4 through 5, further including operations, features, circuitry, logic, means, or instructions, or any combination thereof for activating the heater based at least in part on identifying that the one or more conditions are not met and deactivating the heater based at least in part on identifying that the one or more conditions are met.

Aspect 7: The method, apparatus, or non-transitory computer-readable medium of any of aspects 1 through 6, where the first threshold includes a temperature of negative 35 degrees Celsius and the second threshold includes a temperature of negative 30 degrees Celsius.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 8: A memory system, including: one or more memory dies, a memory die of the one or more memory dies including a plurality of array regions; a temperature sensor configured to sense a temperature associated with the memory die; a heater located on the memory die, the heater configured to dissipate heat to one or more array regions of the plurality of array regions while a state of the heater is set to an activated state; and one or more controllers coupled with the temperature sensor and the heater, the one or more controllers configured to: transmit a first signal to set the state of the heater to the activated state based at least in part on the temperature associated with the memory die being equal to or less than a first threshold; and transmit a second signal to set the state of the heater to a deactivated state based at least in part on the temperature associated with the memory die being greater than or equal to a second threshold, the second threshold being greater than the first threshold.

Aspect 9: The memory system of aspect 8, where the heater includes: a set of heating blocks, where each heating block is associated with a respective array region of the plurality of array regions.

Aspect 10: The memory system of aspect 9, where each heating block of the set of heating blocks includes one or more transistors configured to generate at least a portion of the heat.

Aspect 11: The memory system of any of aspects 8 through 10, where the one or more controllers are further configured to: receive a positive error signal based at least in part on the temperature associated with the memory die being equal to or less than the first threshold, where the one or more controllers are configured to transmit the first signal based at least in part on the positive error signal; and receive a negative error signal based at least in part on the temperature associated with the memory die being greater than or equal to the second threshold, where the one or more controllers are configured to transmit the second signal based at least in part on the negative error signal.

Aspect 12: The memory system of any of aspects 8 through 11, where the one or more controllers are further configured to: identify whether one or more conditions associated with the memory system are met, where the one or more conditions include a quantity of commands associated with the memory system satisfying a third threshold, an input voltage associated with the memory system satisfying a fourth threshold, or a combination thereof.

Aspect 13: The memory system of aspect 12, further including: a power management circuit coupled with the one or more controllers and configured to monitor the input voltage associated with the memory system.

Aspect 14: The memory system of any of aspects 12 through 13, where the one or more controllers are configured to: transmit the first signal to set the state of the heater to the activated state based at least in part on identifying that the one or more conditions are not met; and transmit the second signal to set the state of the heater to the deactivated state based at least in part on identifying that the one or more conditions are met.

Aspect 15: The memory system of any of aspects 8 through 14, where the first threshold includes a temperature of negative 35 degrees Celsius and the second threshold includes a temperature of negative 30 degrees Celsius.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an A SIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory dies, a memory die of the one or more memory dies comprising a plurality of array regions;
a temperature sensor configured to sense a temperature associated with the memory die;
a heater located on the memory die, the heater configured to dissipate heat to one or more array regions of the plurality of array regions while a state of the heater is set to an activated state; and
one or more controllers coupled with the temperature sensor and the heater, the one or more controllers configured to:
transmit a first signal to set the state of the heater to the activated state based at least in part on the temperature associated with the memory die being equal to or less than a first threshold; and
transmit a second signal to set the state of the heater to a deactivated state based at least in part on the temperature associated with the memory die being greater than or equal to a second threshold, the second threshold being greater than the first threshold.

2. The memory system of claim 1, wherein the heater comprises:
a set of heating blocks, wherein each heating block is associated with a respective array region of the plurality of array regions.

3. The memory system of claim 2, wherein each heating block of the set of heating blocks comprises one or more transistors configured to generate at least a portion of the heat.

4. The memory system of claim 1, wherein the one or more controllers are further configured to:
receive a positive error signal based at least in part on the temperature associated with the memory die being equal to or less than the first threshold, wherein the one or more controllers are configured to transmit the first signal based at least in part on the positive error signal; and
receive a negative error signal based at least in part on the temperature associated with the memory die being greater than or equal to the second threshold, wherein the one or more controllers are configured to transmit the second signal based at least in part on the negative error signal.

5. The memory system of claim 1, wherein the one or more controllers are further configured to:
identify whether one or more conditions associated with the memory system are met, wherein the one or more conditions comprise a quantity of commands associated with the memory system satisfying a third threshold, an input voltage associated with the memory system satisfying a fourth threshold, or a combination thereof.

6. The memory system of claim 5, further comprising:
a power management circuit coupled with the one or more controllers and configured to monitor the input voltage associated with the memory system.

7. The memory system of claim 5, wherein the one or more controllers are configured to:
transmit the first signal to set the state of the heater to the activated state based at least in part on identifying that the one or more conditions are not met; and
transmit the second signal to set the state of the heater to the deactivated state based at least in part on identifying that the one or more conditions are met.

8. A method by a memory system, comprising:
monitoring a temperature associated with a memory die of the memory system;
activating, while the memory system is in operation and based at least in part on the temperature associated with the memory die being equal to or less than a first threshold, a heater located on the memory die, the activating increasing the temperature associated with the memory die; and
deactivating, while the memory system is in operation and based at least in part on the temperature associated with the memory die being equal to or greater than a second threshold that is greater than the first threshold, the heater located on the memory die.

9. The method of claim 8, wherein deactivating the heater comprises:
decreasing the temperature associated with the memory die; or
maintaining the temperature associated with the memory die.

10. The method of claim 8, further comprising:
receiving a positive error signal based at least in part on the temperature associated with the memory die being equal to or less than the first threshold, wherein activating the heater is based at least in part on the positive error signal; and
receiving a negative error signal based at least in part on the temperature associated with the memory die being greater than or equal to the second threshold, wherein deactivating the heater is based at least in part on the negative error signal.

11. The method of claim 8, further comprising:
identifying whether one or more conditions associated with the memory system are met, wherein the one or more conditions comprise a quantity of commands associated with the memory system satisfying a third threshold, an input voltage associated with the memory system satisfying a fourth threshold, or a combination thereof.

12. The method of claim 11, further comprising:
monitoring the input voltage associated with the memory system, wherein identifying whether the one or more conditions associated with the memory system are met based at least in part on monitoring the input voltage associated with the memory system.

13. The method of claim 11, further comprising:
activating the heater based at least in part on identifying that the one or more conditions are not met; and
deactivating the heater based at least in part on identifying that the one or more conditions are met.

14. A memory system, comprising:
one or more memory devices; and
processing circuitry coupled with the one or more memory devices and configured to cause the memory system to:
monitor a temperature associated with a memory die of the memory system;
activate, while the memory system is in operation and based at least in part on the temperature associated with the memory die being equal to or less than a first threshold, a heater located on the memory die, the activating increasing the temperature associated with the memory die; and
deactivate, while the memory system is in operation and based at least in part on the temperature associated with the memory die being equal to or greater than a second threshold that is greater than the first threshold, the heater located on the memory die.

15. The memory system of claim 14, wherein deactivating the heater comprises the processing circuitry configured to cause the memory system to:
decrease the temperature associated with the memory die; or
maintain the temperature associated with the memory die.

16. The memory system of claim 14, wherein the processing circuitry is further configured to cause the memory system to:
receive a positive error signal based at least in part on the temperature associated with the memory die being equal to or less than the first threshold, wherein activating the heater is based at least in part on the positive error signal; and
receive a negative error signal based at least in part on the temperature associated with the memory die being greater than or equal to the second threshold, wherein deactivating the heater is based at least in part on the negative error signal.

17. The memory system of claim 14, wherein the processing circuitry is further configured to cause the memory system to:
identify whether one or more conditions associated with the memory system are met, wherein the one or more conditions comprise a quantity of commands associated with the memory system satisfying a third threshold, an input voltage associated with the memory system satisfying a fourth threshold, or a combination thereof.

18. The memory system of claim 17, wherein the processing circuitry is further configured to cause the memory system to:
monitor the input voltage associated with the memory system, wherein identifying whether the one or more conditions associated with the memory system are met based at least in part on monitoring the input voltage associated with the memory system.

19. The memory system of claim 17, wherein the processing circuitry is further configured to cause the memory system to:
activate the heater based at least in part on identifying that the one or more conditions are not met; and
deactivate the heater based at least in part on identifying that the one or more conditions are met.
